(19) United States
(12) Patent Application Publication
(10) Pub. No.: US 2010/0313603 A1
(43) Pub. Date: Dec. 16, 2010

(54) METHOD FOR MANUFACTURING MOLDING DIE, METHOD FOR MANUFACTURING GLASS GOB, AND METHOD FOR MANUFACTURING GLASS MOLDED ARTICLE

(76) Inventors: NAOYUKI FUKUMOTO, Amagasaki-shi (JP); SHUNICHI HAYAMIZU, Amagasaki-shi (JP); KENTO HASEGAWA, OSAKA (JP)

Correspondence Address: BRINKS HOFER GILSON & LIONE, P.O. BOX 10395, CHICAGO, IL, 60610, US

(21) Appl. No.: 12/796,046

(22) Filed: Jun. 8, 2010

(30) Foreign Application Priority Data
Jun. 12, 2009 (JP) JP2009-140842

(51) Int. Cl. C03B 11/12; C23C 14/34

(52) U.S. Cl. 65/66; 204/192.1

(57) ABSTRACT

This invention provides a method for manufacturing a molding die having excellent durability, with which durability film peeling and air bubbles are effectively reduced. A molding surface having a predetermined shape is formed on a substrate, and a cover layer is deposited on the molding surface by a sputtering method which cover layer is then roughened by etching. In the above method, the cover layer is deposited with the substrate held by a substrate holding member which is rotated around a predetermined rotation axis to vary the relative position between a sputtering target and the substrate holding member in such a way that the angle between the normal line of the surface of the sputtering target and the rotation axis is temporarily varied.

This application is based on Japanese Patent Application No. 2009-140842 filed on Jun. 12, 2009, in Japan Patent Office, the entire content of which is hereby incorporated by reference.

### TECHNICAL FIELD

The present invention relates to methods for manufacturing a molding die, use for manufacturing a glass gob or a glass molded article, from a dropped molten glass droplet, and a method for manufacturing a glass gob and a glass molded article utilizing a molding die manufactured by the manufacturing method.

### BACKGROUND

In recent years, an optical element made of glass has been utilized in a wide range of applications as a lens such as a digital camera, an optical pick up lens for a DVD, a camera lens for a cell phone and a coupling lens for optical communication. As such an optical element made of glass, a molded glass article manufactured by press molding of a glass material by use of a molding die is generally utilized.

As such a manufacturing method of a molded glass article, proposed is a method in which a molten glass droplet at a temperature higher than a lower die is dropped on a lower die which is heated at a predetermined temperature, and the dropped molten glass droplet is subjected to press molding with a lower die and an upper die facing to the lower die to prepare a molded glass article (hereinafter, also referred to as “a liquid drop molding method”). This method has been noted because time necessary for one shot of molding can be made very short because it is possible to manufacture a molded glass article directly from a molten glass droplet.

Further, also known is a method for manufacturing a glass molded article in which a molten glass droplet dropped on a lower die is cooled and solidified without any additional treatment to prepare a glass gob (glass block), and the prepared glass gob is heated together with a molding die to be subjected to press molding (a reheat press method).

However, in these methods, there was a problem that minute concave parts are formed in the central neighborhood of the bottom surface of a molten glass droplet (the contact surface with the lower die) at the time of a dropped molted glass drop collides against the lower die, and air immersed into the concave part (air bubble) is sealed to remain in the concave part on the bottom surface of a glass molded article (air bubbles).

To solve such a problem, proposed is a method utilizing a molding die comprising a substrate on which a cover layer is formed and the surface of the cover layer is roughened to prevent an air bubble from remaining by securing a flow path for air having been immersed into concave parts (refer to PCT International Application Publication No. 2009/016993). Further, in PCT International Application Publication No. 2009/016993, described is a method to deposit a cover layer to be roughened, by a sputtering method.

However, in the case of a molding surface on which cover layer is to be formed has a convex form or a concave form, when the cover layer is formed by a sputtering method as described in PCT International Application Publication No. 2009/016993, film properties and film thickness of the cover layer deposited vary between the central portion and circumferential portion of a molding surface. Therefore, there is a problem that roughening excessively proceeds in the circumferential part to easily generate film peeling in the circumferential portion of the cover layer at the time of roughening processor during manufacturing of a glass molded article.

### SUMMARY

This invention has been made in view of a technical problem such as described above and an object of this invention is to provide a method for manufacturing a molding die which is possible to prevent generation of film peeling and having excellent durability, and is possible to effectively prevent generation of air bubbles. Further, another object of this invention is to provide a method for stably manufacturing a glass gob and a glass molded article.

In view of forgoing, one embodiment according to one aspect of the present invention is a method for manufacturing a molding die to be used for manufacturing a glass gob or a glass molded article, the method comprising the steps of:

forming, in a substrate, a molding surface having a predetermined shape;

forming a cover layer on the molding surface by a sputtering method, while the substrate is being held by a substrate holding member which is being rotated about a predetermined rotation axis, and a relative position between a sputtering target and the substrate holding member is being changed so as to temporarily change an angle between a normal line of a surface of the sputtering target and the rotation axis; and

roughening a surface of the cover layer by an etching method.

According to another aspect of the present invention, another embodiment is a method for manufacturing a glass gob, the method comprising the steps of:

dropping a molten glass droplet on a first molding die; and

cooling the dropped molten glass droplet on the first molding die;

wherein the first molding die is manufactured by the above-mentioned method for manufacturing a molding die.

According to another aspect of the present invention, another embodiment is a method for manufacturing a glass molding article, the method comprising the steps of:

dropping a molten glass droplet on a first molding die; and

press-molding the dropped molten glass droplet with the first molding die and a second molding die facing the first molding die,

wherein at least one of the first molding die and the second molding die is manufactured by the above-mentioned method for manufacturing a molding die.

### BRIEF DESCRIPTION OF THE DRAWINGS

FIGS. 1a, 1b and 1c are cross-sectional views to show a molding die in each step of a process;

FIG. 2 is a drawing to show an example of a sputtering system used in an embodiment;

FIG. 3 is a drawing to show an example of motion of a sputtering target and a substrate holding member;

FIG. 4 is a drawing to show another example of motion of a sputtering target and a substrate holding member;

FIG. 5 is a drawing to show another example of a sputtering system used in an embodiment;

FIGS. 6a and 6b are schematic drawings to explain the meaning of an etching rate;

FIG. 7 is a flow chart to show an example of a method for manufacturing a glass molded article;

FIG. 8 is a schematic drawing (the state in step S103) of a manufacturing system of a glass molded article used in an embodiment; and

FIG. 9 is a schematic drawing (the state in step S105) of a manufacturing system of a glass molded article used in an embodiment.

### DETAILED DESCRIPTION OF THE PREFERRED EMBODIMENT

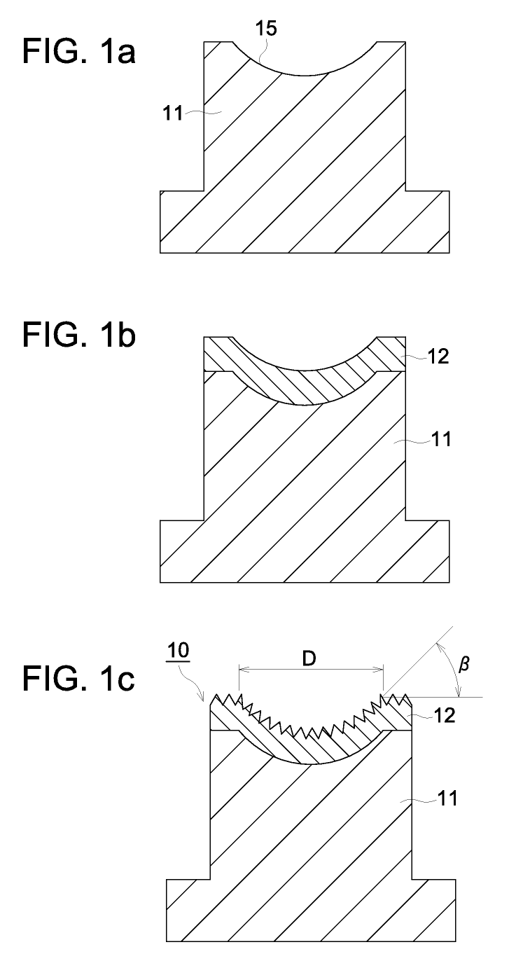

In the following, an embodiment of this invention will be detailed in reference to FIGS. 1a-9; however, this invention is not limited to the embodiment.

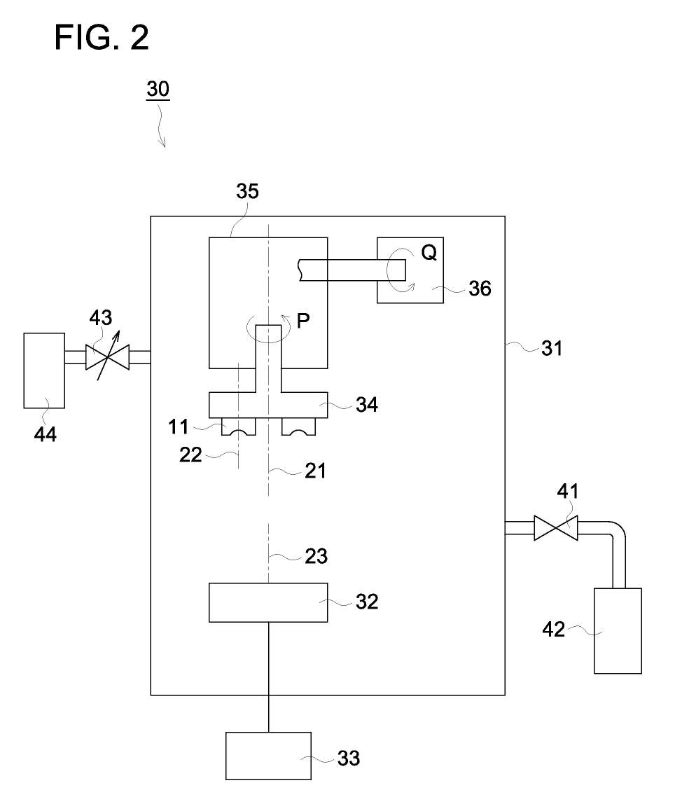

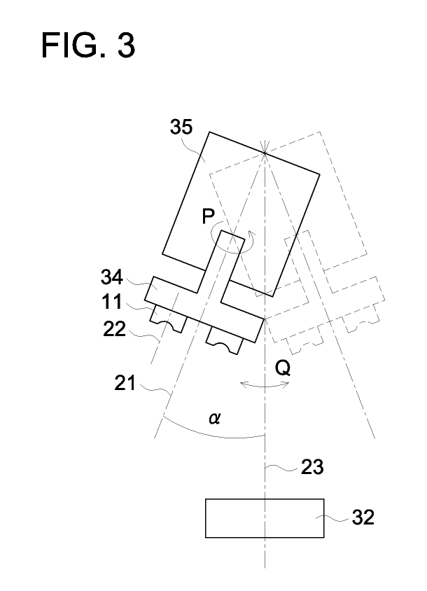

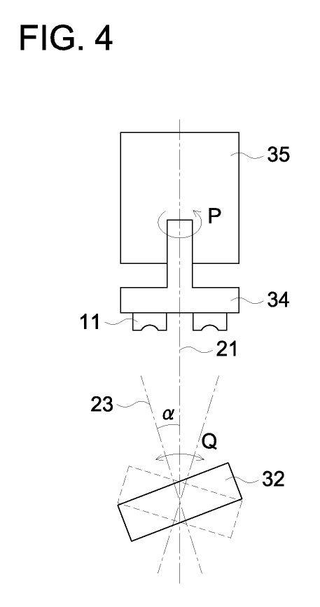

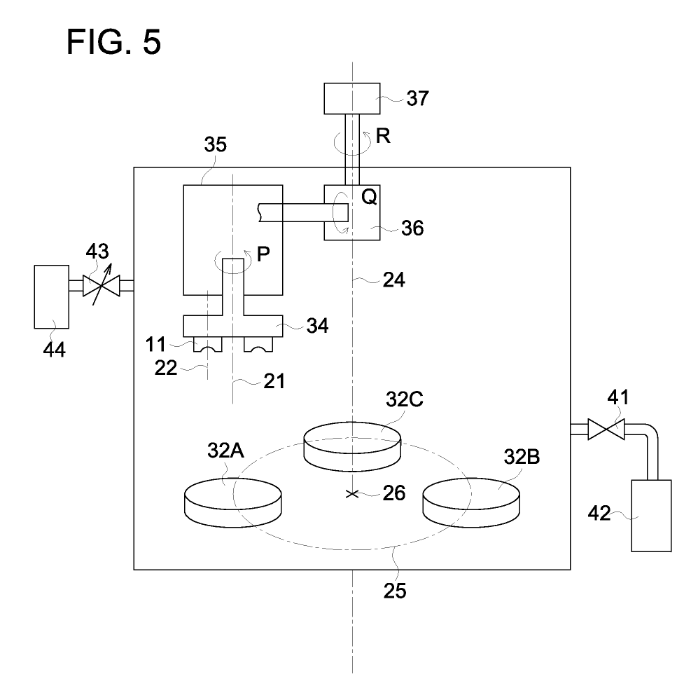

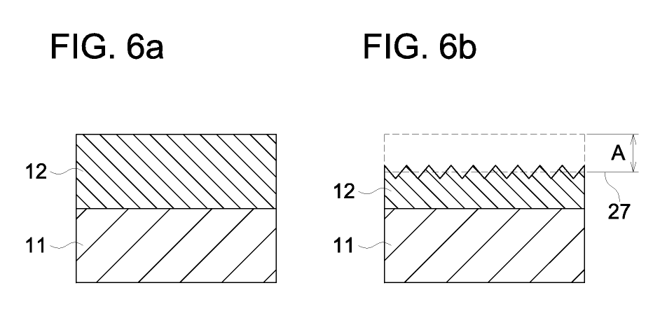

First, a method for manufacturing a molding die will be explained in reference to FIGS. 1a-6. FIGS. 1a, 1b and 1c are cross-sectional views to show the state of a molding die in each step of a process, FIG. 2 is a drawing to show an example of a sputtering system utilized in this embodiment, FIG. 3 is a drawing to show an example of motion of a sputtering target and a substrate holding member, FIG. 4 is a drawing to show another example of motion of a sputtering target and a substrate holding member, FIG. 5 is a drawing to show another example of a sputtering system utilized in this embodiment, and FIG. 6 is a schematic drawing to explain the meaning of an etching rate.

(Substrate)

On substrate 11 which will be a substrate of a molding die to be manufactured, molding surface 15 having a predetermined form corresponding to a shape of a glass gob or a glass molded article to be manufactured is formed in advance (FIG. 1a). The form of molding surface 15 is not specifically limited, however, is particularly effective in the case of having a concave or convex form symmetrical about the central axis. Further, in the conventional method, the difference of film properties or film thickness of cover layer 12 between the central portion and circumferential portion of molding surface 15 is greater as diameter D of molding surface 15 was smaller or inclination angle β with respect to the plane perpendicular to the central axis was greater However, according to this embodiment, differences of film properties and film thickness of cover layer 12 between the central portion and circumferential portion of molding surface 15 is decreased even in such a case. Furthermore, in the case that diameter D of molding surface 15 is not less than 3 mm and not more than 30 mm and inclination angle β against the plane perpendicular to the central axis is not less than 50° and not more than 90°, cover layer 12 is effectively homogenized, which is specifically advantageous. Here, molding surface 15 represents a surface which contacts with a molten glass droplet, to mold (deform) a molten glass droplet. That is to say, it also includes a surface which receives a dropped molten glass droplet, to deform it to manufacture a glass gob in addition to a surface which performs press molding of a molten glass gob to manufacture a glass molded article.

In this embodiment, it is not necessary to roughen substrate 11 before deposition of cover layer 12 because cover layer 12 deposited on substrate 11 is subjected to a roughening process. Therefore, materials of substrate 11 can be selected without considering ease of roughening and durability after roughening and can be appropriately selected depending on the conditions among materials well known in the art as materials for a molding die for press molding of a molten glass droplet. Materials preferably utilized include, for example, various heat-resistant alloys (such as stainless), super hard materials comprising tungsten carbide as a primary component, various ceramics (such as silicon carbide and silicon nitride) and complex materials containing carbon. Further, utilized may be these materials the surface of which is provided with a minutely processed layer such as CVD silicon carbide film.

(Deposition Process)

Next, cover layer 12 is deposited on molding surface 15 by a sputtering method (FIG. 1b). In this embodiment, substrate 11 is held by substrate holding member 34 and cover layer 12 is deposited while rotating substrate holding member 34 around predetermined rotation axis 21 as well as changing the relative positioning between sputtering target 32 and substrate holding member 34 so as to temporarily change angle α between normal 23 of sputtering target 32 and rotation axis 21. Therefore, differences of film properties and film thickness of cover layer 12 between the central portion and circumferential portion of molding surface 15 can be decreased and the difference of progress degree of roughening by etching is also decreased, thus it is possible to prevent excessive progress of roughening at the circumferential portion.

An example of sputtering system 30 utilized in this embodiment is shown in FIG. 2. Sputtering system 30 is equipped, in a vacuum chamber 31, with substrate holding member 34 to hold substrate) 1, sputtering target 32 which is a material of cover layer 12 and is arranged under the substrate holding member, and sputtering power supply 33 to apply a predetermined voltage to sputtering target 32. Further, the sputtering system is also equipped with rotation drive member 35 to rotate (hereinafter, also referred to as “rotation”) substrate holding member 34 around predetermined rotation axis 21, and tilt drive part 36 to vary the relative positioning of sputtering target 32 and substrate holding member 34 so as to temporarily change angle α between normal 23 of the surface of sputtering target 32 and rotation axis 21 (hereinafter, also referred to as “tilt drive”). Further, vacuum chamber 31 is connected to displacement pump 42 for evacuation of the inside of vacuum chamber 31 down to a predetermined vacuum degree via valve 41, and connected to gas bottle 44 for introduction of a sputtering gas into the inside of vacuum chamber 31 via flow rate controlling valve 43.

At the time of deposition of cover layer 12, firstly, substrate 11 is attached to substrate holding member 34 with molding surface 15 facing downward. The number of substrates 11 may be either one or plural. Next, valve 41 is opened to evacuate the inside of vacuum chamber 31 down to a predetermined vacuum degree by displacement pump 42. It is generally preferable to evacuate down to a pressure of not more than 1×10⁻³ Pa. Further, it is also preferable to provide a heater in substrate holding member 34 to heat substrate 11 at a predetermined temperature. After evacuating the inside of vacuum chamber 31 down to a predetermined vacuum degree, flow rate controlling valve 43 is opened to introduce a sputtering gas from gas bottle 44, and a predetermined voltage is applied to sputtering target 32 by sputtering power supply 33 to generate plasma in the neighborhood of the upper surface of sputtering target 32. Thereby, ions of sputtering gas collide against sputtering target 32 to spatter composite elements of sputtering target as sputtering particles. The sputtered sputtering particles reach substrate 11, which is arranged above, and are accumulated to form cover layer 12 on molding surface 15.

In this embodiment, cover layer 12 is deposited while performing the above-described rotation and tilt drive. Rotation and tilt drive will be explained in reference to FIGS. 2 and 3. Rotation is rotation of substrate holding member 34 around a predetermined rotation axis 21, and in this embodiment, substrate holding member 34 is rotated in the direction of arrow P in the drawing by rotation drive member 35. It is preferable to make rotation axis 21 to be approximately parallel to central axis 22 of molding surface 15. Thus, differences of film properties and film thickness are more effectively decreased. The rotation speed may be appropriately set depending on the holding position of substrate 11 or the form and size of molding surface 15. For example, it may be set in the range of 2-10 rpm.

The tilt drive is to vary the relative positioning of sputtering target 32 and substrate holding member 34 so as to temporarily vary angle α between normal 23 of sputtering target 32 and rotation axis 21, and in this embodiment, substrate holding member 34 is driven in the direction of arrow Q in the drawing by tilt drive part 36. The magnitude of angle α and the rate of drive may be appropriately set depending on the holding position of substrate 11, the form of molding surface 15 and the distance between sputtering target 32 and substrate 11. For example, it is preferable to set angle α to be 10°-45° for left and right each and to repeatedly drive at a rate of 0.5-2 rpm. Angle α of tilt drive is preferably α>βₘₐₓ/4.5 and more preferably α>βₘₐₓ/2.5 when the maximum value of inclination angle β of molding surface 15 is βₘₐₓ. Further, instead of driving substrate holding member 34 by tilt drive part 36, sputtering target 32 may be driven in the direction of arrow Q as shown in FIG. 4 so as to temporarily vary angle α between normal 23 of the surface of sputtering target 32 and rotation axis 21 sputtering. In either case, in order not to generate asymmetry of cover layer 12 on molding surface 15, one cycle in P direction needs to be different from one cycle in Q direction.

The material of cover layer 12 is not specifically limited; however, it is preferably that materials are easily roughened by etching and have low reactivity with glass. Among them, metal chromium, metal aluminum, metal titanium, oxide and nitride thereof, or mixture thereof can be preferably utilized. A film of these materials can be easily deposited and can be easily roughened by etching. Further, chromium, aluminum and titanium has a characteristic that when one of those is contained in cover layer 12, it is oxidized by heating in atmosphere to form a stable oxide layer on the surface. Since these oxides have small standard free energy of formation (standard Gibb's energy of formation) and are very stable, there is a great advantage of not easily reacting even in contact with high temperature molten glass droplet. Among them, it is more preferable to provide cover layer 12 containing chromium element, since its oxide is very stable.

In the case of depositing cover layer 12 containing two kinds of elements or more, deposition may be performed utilizing sputtering target 32 containing both element at a predetermined ratio, or deposition by complex sputtering may be performed utilizing plural sputtering targets 32 containing each element. FIG. 5 shows an example of a system to perform complex sputtering utilizing three sputtering targets 32A, 32B and 32C. In the system of FIG. 5, three sputtering targets 32A, 32B and 32C are arranged on the circumference of circle 25, and the system is equipped with orbital drive section 37 to rotate substrate holding member 34 in the direction of arrow R in the drawing around axis 24 which passes through center 26 of the circumference of circle 25. By deposition utilizing such a system while performing rotation (orbital motion) so as to make substrate holding member 34 pass over sputtering targets 32A, 32B and 32C in addition to the above-described rotation and tilt drive, it is possible to more uniformly deposit cover layer 12 containing not less than two kinds of elements.

The cover layer 12 may have at least an enough thickness for the micro roughness to be formed by roughening by etching, and is generally preferably not less than 0.05 μm. On the contrary, when cover layer 12 is excessively thick, defects such as film peeling may be easily generated. Therefore, the thickness of cover layer 12 is preferably 0.05-5 μm and specifically preferably 0.1-1 μm. Further, in the case of molding surface 15 has a concave or convex form symmetric about central axis 22, the thickness of cover layer 12 over the whole range of molding surface 15 is preferably not less than 0.8 times and not more than 1.2 times, and more preferably not less than 0.9 times and not more than 1.1 times, of the film thickness at the position of central axis 22, from the point of view of sufficiently decreasing the difference of progress of roughening between the central portion and circumferential portion of molding surface 15 and assuring the effect to prevent excessive roughening in the circumferential portion.

Further, if the number of diffraction peaks or the magnitude relation of strength in the diffraction peaks, of cover layer 12, detected in the evaluation with XRD (X-ray diffraction) vary in different positions, a difference in etching rate may be caused, and a difference of the proceeding rate of roughening may be thus produced. In such a point of view, the conditions of rotation and tilt drive at the time of deposition of cover layer 12 are preferably set so as to make the number of diffraction peaks or the magnitude relation of strength between the diffraction peak of cover layer 12 detected with XRD substantially identical over the whole molding surface 15. For example, in the case of utilizing chromium film as cover layer 12, it is effective to make equal magnitude relation between the two diffraction peaks: the peak of (110) plane appearing in the vicinity of 2θ=44°, and the peak of (200) plane appearing in the vicinity of 2θ=64°. The measurement of diffraction peaks measured with XRD may be conducted by use of a general X-ray diffractometer (such as X-ray diffractometer RINT 2500 manufactured by Rigaku Co., Ltd.), and the measurement conditions may be appropriately selected depending on the object. For example, in the case of utilizing chromium film as cover layer 12, measurement may be performed under the conditions of the range of 0-80° based on a θ-2θ method, a sampling width of 0.02° and a scanning rate of 5°/min.

(Roughening Process)

Next, roughening by etching of the surface of cover layer 12 is performed (FIG. 1c). In this embodiment, since the differences of film properties and film thickness between the central portion and circumferential portion of molding surface 15 are small as described above, difference in progress of roughening is also small, and thus the peeling of film due to excessive roughening in the circumferential portion is controlled.

Etching may be performed either by wet etching utilizing liquid or dry etching utilizing gas. Among them, wet etching utilizing liquid is preferable because it requires no expensive facilities and enables easy formation of uniform roughness.

In the case of wet etching, a reactive etching solution is brought in contact with cover layer 12 to make reaction, whereby cover layer 12 is subjected to roughening to form roughness in the surface. Cover layer 12 may be immersed in an etching solution stored in a vessel or a predetermined amount of etchant may be supplied on cover layer 12. Further, a method to spray an etchant in a mist form is also possible. As an etchant, an etchant well known in the art matching the material of cover layer 12 can be appropriately selected. For example, in the case of cover layer 12 being chromium film, an acidic solution containing ammonium ceric nitrate or an alkaline solution containing potassium ferricyanate and potassium hydroxide is preferably utilized.

Further, in the case of dry etching, an etching gas is introduced into a vacuum chamber and plasma is generated by application of high frequency waves, whereby cover layer 12 is subjected to roughening by ions and radicals generated by plasma. This method is also referred to as plasma etching or reactive ion etching (RIE). It is a preferable method because of such as small environmental load due to no generation of effluent, little contamination of the surface by foreign matters and excellent reproducibility of the process. As a dry etching system, a parallel plate type, a barrel (cylindrical) type, a magnetron type and an ECR type and the like may be appropriately selected from systems well known in the art, and there is no specific limitation. As an etching gas, either an inert gas such as Ar or a highly reactive gas containing halogen such as F, Cl and Br may be utilized. Among them, a gas containing halogen such as F, Cl and Br (for example, such as CF₄, SF₆, CHF₃, Cl₂, BCl₃ and HBr) shows high reactivity and enables processing in a short time. Further, these gases may be used in combination with O₂ or N₂ and the like.

In either one of the above-described methods, difference in etching rate will be generated if film properties of cover layer 12 are different between the central part and the circumferential part of molding surface 15. However, since film properties and film thickness of cover layer 12 is made to be uniform in this embodiment, the difference in roughening is small. The etching rate of cover layer 12 varies depending on the magnitude of energy possessed by sputtering particles reaching the deposition surface at the time of deposition of cover layer 12 by sputtering, and can be controlled by the conditions of rotation and tilt drive. In such a view point, it is preferable to set the conditions of rotation and tilt drive at the time of deposition of cover layer 12 so as to make the etching rate of cover layer 12 as uniform as possible. In particular, it is preferable to set the etching rate of cover layer 12 over the whole region to not less than 0.5 times and not more than 5 times of the etching rate at the position of central axis 22 of molding surface 15.

The meaning of an etching rate in this description will now be explained in reference to FIGS. 6a and 6b. FIG. 6a is a drawing to show the initial state before etching, and cover layer 12 is formed on substrate 11. FIG. 6b) shows a state after etching for processing time t. In this case, decreased amount A of thickness of cover layer 12 divided by processing time t is an etching rate. Here, minute roughness is formed on the surface of cover layer 12 by etching, and average line 27 of the roughness is utilized for calculation of an etching rate.

Roughening by etching is preferably peg formed so as to make the arithmetic mean roughness (Ra) of the surface of cover layer 12 be 0.01-0.2 μm and the mean length of roughness curve elements (RSm) be not more than 0.5 μm. By making the arithmetic mean roughness (Ra) and the mean length of roughness curve elements (RSm) in these ranges, it is possible to more effectively prevent generation of air bubbles in a glass molded article to be generated. Herein, the arithmetic mean roughness (Ra) and the mean length of roughness curve elements (RSm) are roughness parameters defined in JIS B 0601:2001. In this embodiment, measurement of these parameters is performed by use of a measurement system such as an AFM (an atomic force microscope) having a spatial resolution of not more than 0.1 μm.

Here, the whole surface of cover layer is not necessarily roughened etching, and it is enough that at least the region to contact with molten glass droplet 50 is roughened. Further, in this embodiment, an example in which cover layer 12 is constituted by a single layer was explained; however, cover layer 12 may have a multi-layered structure constituted by two layers or more. For example, an intermediate layer to enhance adhesion between substrate 11 and cover layer 12 may be provided, and a protective layer to protect the surface may be provided on cover layer on which roughness has been formed by a roughening treatment.

(Method for Manufacturing Glass Molded Article)

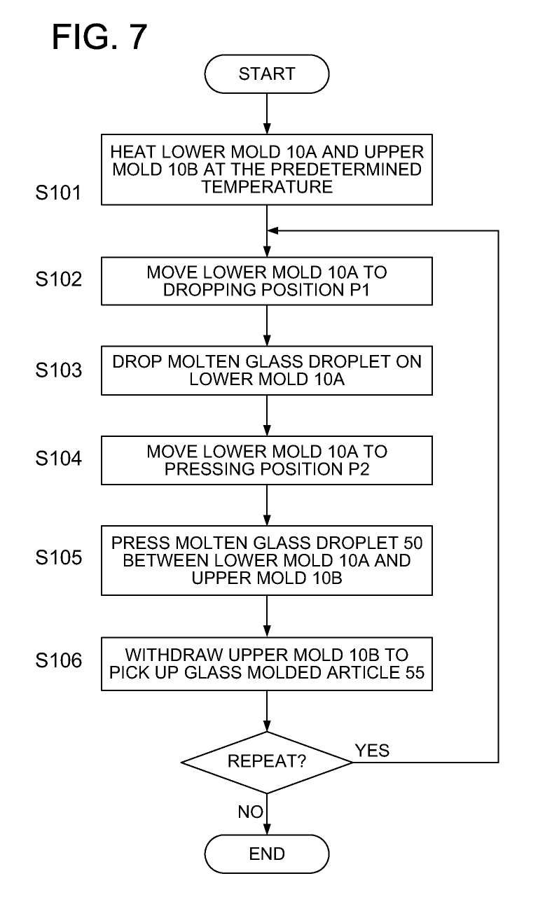

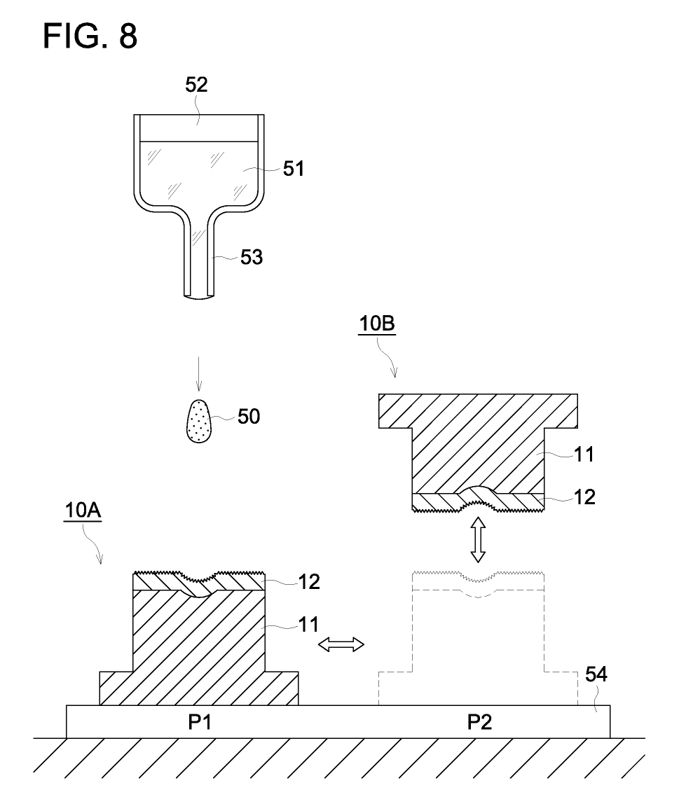

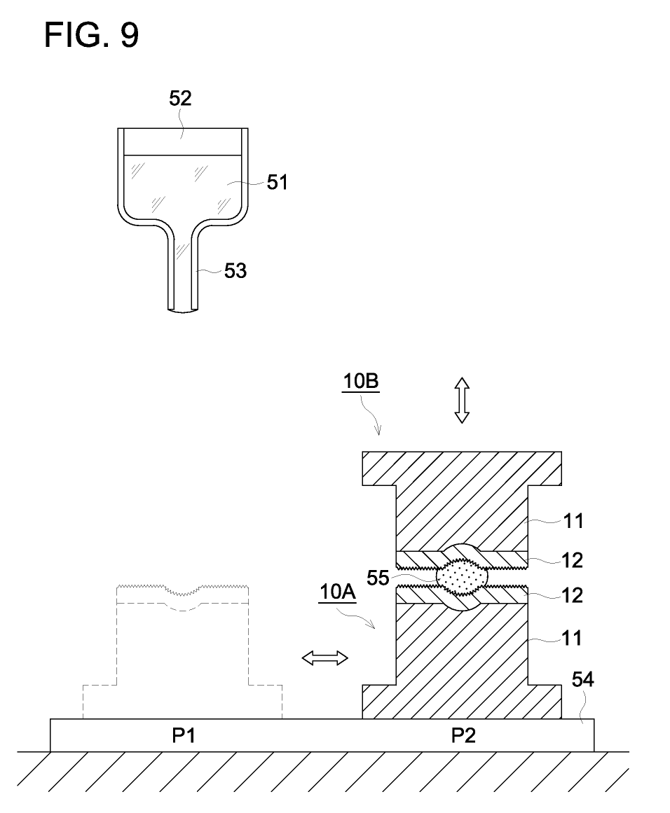

Next, a method for manufacturing a glass molded article will be explained in reference to FIGS. 7-9. FIG. 7 is a flow chart to show an example of a method for manufacturing a glass molded article, and FIGS. 8 and 9 are schematic drawings of a manufacturing system of a glass molded article utilized in this embodiment. FIG. 8 shows a process (step S103) to drop a molten glass droplet on a lower die, and FIG. 9 shows a process (step S105) to press a molten glass droplet with a lower die and an upper die.

The manufacturing system of a glass molded article shown in FIGS. 8 and 9 is equipped with melting bath 52 to store molten glass 51, dropping nozzle 53 connected to the bottom of melting bath 52 to drop molten glass droplet 50, lower die 10A to receive dropped molten glass droplet 50, and upper die 10B to perform press molding of molten glass droplet 50 together with lower die 10A. Molding die 10 manufactured by the above-described method may be utilized as lower die 10A or as upper die 10B. In the case of utilizing molding die 10 as lower die 10A, it is possible to effectively prevent air bubbles generated at the time of receiving molten glass droplet 50. Further, in the case of utilizing molding die 10 as upper die 10B, it is possible to effectively prevent air bubbles generated at the time of molding dropped molten glass droplet 50. An example in which molding die is utilized as both of lower die 10A and upper die 10B will now be explained; however, the above-described advantage can be achieved by utilizing molding die 10 at least as one of lower die 10A and upper die 10B.

Lower die 10A and upper die 10B are constituted so as to be heated at a predetermined temperature by a heating section which is not shown in the drawing. As a heating section, a heating section well known in the art can be utilized by appropriate selection. For example, there can be used a cartridge heater which is utilized being berried in the inside, a sheet form heater which is utilized in contact with the outside surface, an infrared heater and a high frequency induction heater. It is preferable to adopt a constitution in which temperature can be controlled independently for lower die 10A and upper die 10B. Lower die 10A is arranged to be moved along guide 54 between the position to receive molten glass droplet 50 (dropping position P1) and the position to perform press molding (pressing position P2) by a drive section which is not shown in the drawing. Further, upper die 10B is arranged to be moved in the direction to press molten glass droplet 50 (the up-and-down direction in the drawing) by a drive section which is not shown in the drawing.

In the following description, each process of a method for manufacturing glass molded article 55 will be explained in order according to the flow chart shown in FIG. 7.

First, lower die 10A and upper die 10B are heated at a predetermined temperature (step S101). As the predetermined temperature, appropriately selected is a temperature at which a good surface can be transferred on a glass molded article by press molding. The heating temperatures of lower die 10A and upper die 10B may be the same or different from each other. A suitable temperature is appropriately set depending on various conditions such as the type, form, and size of glass; and the material and the size of a molding die for molding glass. Generally, the temperature is preferably set at approximately from Tg−100° C. to Tg+100° C., when glass transition temperature of utilized glass is Tg.

Next, lower die 10A is moved to dropping position P1 (step S102) and molten glass droplet 50 is dropped from dropping nozzle 53 (step S103) (refer to FIG. 8). Dropping of molten glass droplet 50 is performed by heating dropping nozzle 53 connected to melting bath 52 for storing molten glass 51 up to a predetermined temperature. When dropping nozzle 53 is heated at a predetermined temperature, molten glass 51 stored in meting bath 52 is supplied to the top portion of dropping nozzle 53 by its own weight, and the molten glass is held there as a liquid droplet form due to its surface tension. When the molten glass held at the top portion of dropping nozzle 53 reaches a certain mass, it is separated by itself from dropping nozzle 53 by gravity, and falls downward as molten glass droplet 50.

The mass of molten glass droplet 50 dropped from dropping nozzle 53 can be adjusted depending on the outer diameter of the top portion of dropping nozzle 53, and it is possible to drop molten glass droplet 50 of approximately 0.1-2 g although it depends on a kind of glass. Further, molten glass droplet 50 dropped from dropping nozzle 53 may be once made to collide against a member having penetrating micro pores so that the part of molten glass droplet having collided passes through the penetrating micro pores, whereby micronized molten glass droplets may be dropped on lower die 10A. By utilizing such a method, since a molten glass droplet, for example, as minute as 0.001 g can be prepared, it is possible to manufacture a more minute molded glass article compared to the case of directly receiving molten glass droplet 50 dropping from dropping nozzle 53 on lower die 10A.

The kind of glass utilized is not specifically limited and glass well known in the art can be appropriately selected depending on the application and be used. Examples include optical glass such as borosilicate glass, silicate glass, phosphate glass and lanthanum type glass is listed.

Next, lower die 10A is moved to pressing position P2 (step S104) and upper die 10B is moved downward, whereby molten glass droplet 50 is press-molded with lower die 10A and upper die 10B (step S105) (refer to FIG. 9). Molten glass droplet 50 received by lower die 10A is cooled by heat radiation through the contact surface with lower die 10A and upper die 10B and solidified to be molded glass article 55 during being press-molded. When molded glass article 55 is cooled to a predetermined temperature, upper die 10B is moved upward to release pressure. Generally, pressure is preferably released after cooling to a temperature near Tg of glass, although it depends on the kind of glass, the size, form and required precision of molded glass article 55.

The load applied to press molten glass droplet 50 may be temporarily kept constant or varied with time. The magnitude of the load applied may be appropriately set depending on the size of molded glass article 55 to be manufactured. The drive means to vertically move upper die 10B is not specifically limited and a drive section well known in the art such as an air cylinder, an oil pressure cylinder and an electric cylinder employing a servo motor can be utilized by appropriate selection.

Thereafter, upper die 10B is moved upward, and molded glass article 55 having been solidified is picked up (step S106) to complete manufacture of molded glass article 55. Then, in the case of successive manufacturing of molded glass article 55, lower die 10A is moved to dropping position P1 again (step S102) and processes to continue thereto is repeated. Here, a method for manufacturing a molded glass article of this embodiment may includes processes other than those explained here. For example, provided may be a step to inspect the form of molded glass article 55 before picking up molded glass article 55, or a step to clean lower die 10A or upper die 10B after picking up molded glass article 55.

According to a method for manufacturing a glass molded article of this embodiment, since molding die 10, in which cover layer 12 has been deposited while performing rotation and tilt drive, is utilized as at least one of lower die 10A and upper die 10B, the film properties and the film thickness are made uniform, and difference in roughening between the central part and circumferential part of molding surface 15 is small. Thus, it is possible to prevent generation of air bubbles at the time of receiving molten glass droplet 50 and performing press molding, and possible to restrain film peeling of cover layer 12. Therefore, a glass molded article without air bubbles can be stably manufactured.

Glass molded article 55 manufactured by a manufacturing method of this embodiment can be utilized as various optical elements such as a picture-taking lens of a digital camera, an optical pickup lens of a DVD and a coupling lens for optical communication.

Here, in the case of utilizing molding die 10 as lower die 10A, it is also possible to prepare a glass gob (glass block) by cooling and solidifying molten glass droplet 50 dropped on lower die 10A in step S103 as is without press-molding. Also in this case, it is possible to prevent generation of film peeling in cover layer 12, and possible to effectively prevent generation of air bubbles at the time of receiving molten glass droplet 50, whereby a glass gob without air bubbles can be stably manufactured. The details of each step are similar to the steps in the case of manufacturing a glass molded article. A glass gob manufactured can be utilized as a raw material glass (a glass pre-form) for manufacturing an optical element by a reheat method.

According to this embodiment, since a substrate is held by a substrate holding member and a cover layer is deposited while varying the relative positioning of a sputtering target and the substrate holding member so as to vary the angle between the normal line of the surface of a sputtering target and the rotation axis as well as rotating the substrate holding member around a predetermined rotation axis, it is possible to decrease differences in film properties and film thickness of a cover layer between the central portion and circumferential portion of a molding surface. Whereby, a difference in roughening between the central portion and circumferential portion of a molding surface will be also decreased, and excessive roughening will be controlled in the circumferential portion. Therefore, film peeling is decreased, and air bubbles will also be decreased, whereby a molding die of excellent durability is manufactured. Further, by utilizing a molding die manufactured by the above-described method, a glass gob and a glass molded article without air bubbles are stably manufactured.

### EXAMPLES

In the following, examples conducted to confirm the advantages of this invention will be explained; however, this invention is not limited thereto.

### Example

According to steps shown in FIGS. 1a, 1b and 1c, molding die 10 was manufactured by the above-described method. The material of substrate 11 was sintered silicon carbide (SiC). Molding surface 15 was a concave surface symmetric about central axis 22, and had a diameter of 5 mm and the maximum inclination angle of 70°.

Substrate 11 was attached on substrate holding member 34 of sputtering system 30 shown in FIG. 2. At this time, central axis 22 of molding surface 15 was arranged to be parallel to rotation axis 21 of substrate holding member 34. As sputtering target 32, a chromium target having a diameter of 152 mm (6 inches) was utilized, and the distance between sputtering target 32 and molding surface 15 was set to 65 mm.

Thereafter, substrate 11 is heated up to 200° C. while evacuating the inside of vacuum chamber 31 with valve 41 opened. After the inside of vacuum chamber 31 reached a high vacuum of 10⁻³ Pa, a sputtering gas of 1 Pa was introduced from gas bottle 44 by opening flow rate controlling valve 43. Argon gas was utilized as a sputtering gas. Then, a high frequency electric power of 300 W was applied to the sputtering target while performing rotation and tilt drive by operation rotation drive member 35 and tilt drive part 36, whereby chromium film (cover layer 12) of 0.5 μm was deposited. The rotation rate of the rotation was set to 5 rpm. Further, tilt drive made the substrate back and forth continuously at a rate of 1 rpm and an angle of 30° toward left and right each.

After finishing deposition, substrate 11 was taken out from vacuum chamber 31 and the surface of cover layer 12 was roughened by etching. As the etching solution, a chromium etching solution containing ammonium eerie nitrate available on the market (ECR-2), manufactured by Nacali Tesque Co., Ltd.), was utilized. The surface of cover layer 12 after roughening showed arithmetic mean roughness Ra of 0.1 μm and mean length of a roughness curve elements RSm of 0.1 μm both in the central portion and in the circumferential portion. Here, arithmetic mean roughness Ra and mean length of a roughness curve elements RSm were measured by an AFM (D3100, manufactured by Digital Instruments).

Molding die 10 prepared in the above manner was utilized as lower die 10A and upper die 10B, and a glass molded article was manufactured according to the flow chart shown in FIG. 7. As a glass material, phosphate type glass was utilized. The temperature of dropping nozzle 53 was set to 1,000° C. at the vicinity of its apex portion so that molten glass droplet 50 of approximately 190 mg was dropped. Regarding heating of lower die 10A and upper die 10B, lower die 10A was set to 500° C., and upper die 10B was set to 450° C. for. The load for press molding was set to 1,800 N.

Each process was repeated to prepare 1,000 pieces of glass molded articles and the prepared glass molded articles were observed to evaluate the presence or absence of air bubbles and film peeling of cover layer 12. In this embodiment, with respect to all the 1,000 pieces of glass molded articles, no generation of air bubbles and no film peeling of cover layer 12 were observed.

### Comparative Example 1

Different from the example, cover layer 12 was deposited in the state where molding surfacr 15 and sputtering target 32 were stationarily facing each other without performing rotation and tilt drive. The film thickness of cover layer was 0.5 μm. Other conditions were identical to those of the example. After finishing deposition, roughening by etching was performed similarly to the example. However, because progress of roughening was faster in the circumferential portion of molding surface 15 compared to the central portion, and film peeling was generated in the circumferential portion before the roughness at the central portion reached the similar roughness to the example, these dies were not utilized for manufacturing glass molded articles.

### Comparative Example 2

In a similar manner to comparative example 1, cover layer 12 was deposited in a state where molding surface 15 and sputtering target 32 were stationarily facing each other without performing rotation and tilt drive. It should be noted that the film thickness of cover layer 12 was set to 1.5 μm. After finishing deposition, roughening by etching was performed similarly to the example. Progress of roughening was faster in the circumferential portion of molding surface 15 compared to the central portion, and arithmetic mean roughness Ra in the circumferential portion was 0.3 μm when arithmetic mean roughness Ra in the central portion reached 0.1 μm. Thereafter, the presence and absence of air bubbles and film peeling of cover layer 12 were evaluated by preparing glass molded articles similarly to the example. In comparative example 2, although generation of air bubbles could be reduced, film peeling in the circumferential portion of molding surface 15 was generated at a time of molding of 100 shots, and glass molded articles manufactured after that time did not satisfy the required quality because of the poor external appearance.

As described above, in the cases of comparative examples 1 and 2, since rotation and tilt drive were not performed during deposition of cover layer 12, the difference of progress of roughening between the central portion and circumferential portion of molding surface 15 was large resulting in excessive roughening in the circumferential portion, which disabled stable manufacturing of a glass molded article. On the contrary, in the example, the difference of progress of roughening between the central portion and circumferential portion of molding surface 15 was decreased by performing rotation and tilt drive during deposition. Whereby, generation of film peeling in the circumferential portion has been restrained, and the durability of a molding die was improved, and glass molded articles without air bubbles were stably manufactured.

What is claimed is:

1. A method for manufacturing a molding die to be used for manufacturing a glass gob or a glass molded article, the method comprising the steps of:
forming, in a substrate, a molding surface having a predetermined shape;
forming a cover layer on the molding surface by a sputtering method, while the substrate is being held by a substrate holding member which is being rotated about a predetermined rotation axis, and a relative position between a sputtering target and the substrate holding member is being changed so as to temporarily change an angle between a normal line of a surface of the sputtering target and the rotation axis; and
roughening a surface of the cover layer by an etching method.

2. The method of claim 1, wherein the molding surface is concave or convex and is rotationally symmetric about a central axis, and the central axis is substantially parallel to the rotation axis.

3. The method of claim 2, wherein the molding surface has a diameter of not less than 3 mm and not more than 30 mm, and an inclination angle of the molding surface with respect to the central axis has a maximum value of not less than 50 degrees and not more than 90 degrees.

4. The method of claim 2, wherein at any position on the molding surface, a thickness of the cover layer is not less than 0.8 times and not more than 1.2 times of a thickness of the covering layer at a position of the central axis.

5. The method of claim 2, wherein at any position on the molding surface, an etching rate of the cover layer in the step of roughening is not more than 0.5 times and not less than 5 times of an etching rate of the cover layer at a position of the central axis

6. The method of claim 1, wherein the cover layer is formed in the step of forming a cover layer such that a number of diffraction peaks detected by XRD and a magnitude relation between the diffraction peaks are substantially the same at any position on the molding surface.

7. The method of claim 1, wherein the cover layer contains at least one element selected from the group consisting of chromium, aluminum, and titanium.

8. A method for manufacturing a glass gob, the method comprising the steps of:
dropping a molten glass droplet on a first molding die; and
cooling the dropped molten glass droplet on the first molding die;
wherein the first molding die is manufactured by the method of claim 1.

9. A method for manufacturing a glass molding article, the method comprising the steps of:
dropping a molten glass droplet on a first molding die; and
press-molding the dropped molten glass droplet with the first molding die and a second molding die facing the first molding die,
wherein at least one of the first molding die and the second molding die is manufactured by the method of claim 1.
